(19) United States
(12) Patent Application Publication
(10) Pub. No.: US 2026/0354092 A1
(43) Pub. Date: Nov. 5, 2026

(54) SPATIAL AWARENESS SYSTEM IN SEMICONDUCTOR PROCESSING TOOLS

(71) Applicant: Lam Research Corporation, Fremont, CA (US)

(72) Inventors: Gene Jacob Kapel, Foster City, CA (US); Travis Robert Taylor, Portland, OR (US)

(21) Appl. No.: 19/488,061

(22) PCT Filed: Apr. 29, 2024
(86) PCT No.: PCT/US2024/026874

§ 371 Date: Nov. 25, 2025

Related U.S. Application Data
(60) Provisional application No. 63/470,734, filed on Jun. 2, 2023.

(51) Int. Cl. H10P 72/00

(52) U.S. Cl. CPC H10P 72/0606; H10P 72/0612

(57) ABSTRACT

A method for sensor-assisted signal calibration of a semiconductor processing tool includes decoding a plurality of sensor measurements received from at least one range-finding sensor of a sensor array associated with the semiconductor processing tool. A presence of a disrupting object is detected within an access zone of the semiconductor processing tool based on the plurality of sensor measurements. A deviation of at least one signal characteristic of a wireless signal from a pre-configured value is detected. A correlation is generated based on the deviation of the at least one signal characteristic of the wireless signal and the presence of the disrupting object. A mitigation action associated with the wireless signal is performed at least partially based on the correlation.

### CLAIM OF PRIORITY

This application claims the benefit of priority to U.S. Patent Application Ser. No. 63/470,734, filed on Jun. 2, 2023, which is incorporated by reference herein in its entirety.

### FIELD

The present disclosure generally relates to methods and systems for performing the detection of object placement or object movement in the vicinity of signal transmission zones of semiconductor manufacturing equipment and managing signal transmission (e.g., wireless connectivity) based on such detection. Some more particular examples relate to systems and methods for assisting in the calibration of a wafer-handling robot for a semiconductor processing tool.

### BACKGROUND

A substrate processing system may be used to perform deposition, etching, and/or other treatment of substrates such as semiconductor wafers. During processing, a substrate is arranged on a substrate support in a processing chamber of the substrate processing system. Gas mixtures, including one or more precursors, are introduced into the processing chamber, and plasma may be struck to activate chemical reactions.

The substrate processing system may include a plurality of substrate processing tools arranged within a fabrication room. Each of the substrate processing tools may include a plurality of process modules. In some sub-processes, certain components are controlled by wireless communications. For example, systems such as integrated wireless adaptive positioning systems (APS) and associated routines can be used for automated wafer handling health checks, as well as calibration. Personnel access and disruptive foreign objects placed in a path between a wireless router and an APS can negatively impact wireless connectivity and cause calibration and substrate processing faults.

The background description provided here presents the general context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### BRIEF SUMMARY

Some examples include a range-finding sensor to detect when a substrate processing tool is accessed by human personnel or has an object placed upon it (or in its vicinity). As used herein, the term “disruptive object” indicates a human (e.g., human personnel such as service personnel servicing the substrate processing tool) and/or an object located in the vicinity of the substrate processing tool (e.g., within a pre-configured distance from the tool, placed on a surface of the tool, or placed within a specific space associated with the tool such as an access zone). The sensor can provide detection and distance information to help identify the disruptive object and diagnose failures (e.g., weakened communication signal or another type of deviation of a signal characteristic from a pre-configured or desired value) that may have been caused by such personnel access or object placement. In some aspects, mitigation action is performed based on the detected failures. For example, suppose a weakened communication signal is detected due to the presence of a disruptive object within the access zone of the substrate processing tool. In that case, a mitigation action is performed, which can include adjusting the signal strength, re-routing the affected signal, generating a notification of the detected failure for communication within the access zone, etc.

In some particular examples, at least one sensor is located on a semiconductor manufacturing tool or module to detect and monitor, using range finding and distance measurement, a disruptive object presence in a specified field of view (FoV). The sensor can continuously record detection timestamps and track the detected disruptive object location relative to the sensor while the disruptive object is in the FoV. The information enables operators to know, for example, when and where the disruptive object (e.g., human personnel or a non-human object) has entered a specific space, how long they were there, the movement path and direction of the disruptive object, and what part of the tool or component was accessed. Some examples use captured data to optimize wireless connectivity and fine-tune signal transmission parameters. In some examples, the disclosed techniques use a machine-learned model or other training algorithm or feedback technique to optimize signal transmission.

In some embodiments, a system for sensor-assisted signal calibration of a semiconductor processing tool is provided. The system includes a sensor array comprising a plurality of range-finding sensors, the plurality of range-finding sensors disposed within an access zone of the semiconductor processing tool. The system further includes a controller communicatively coupled to the sensor array. The controller is configured to decode a corresponding plurality of sensor measurements received from the plurality of range-finding sensors. The controller is further configured to detect a presence of a disrupting object within the access zone of the semiconductor processing tool based on the corresponding plurality of sensor measurements. The controller is further configured to detect a deviation of at least one signal characteristic of a wireless signal from a pre-configured value, where the wireless signal is propagating through the access zone, and the deviation is detected while the disrupting object is present within the access zone. The controller is further configured to perform a mitigation action associated with the wireless signal based on detecting the deviation.

In some embodiments, a system for sensor-assisted signal calibration of a semiconductor processing tool includes a sensor array comprising at least one range-finding sensor. The at least one range-finding sensor is disposed within an access zone of the semiconductor processing tool. The system includes a controller communicatively coupled to the sensor array. The controller is configured to decode a plurality of sensor measurements received from the at least one range-finding sensor, detect a presence of a disrupting object within the access zone of the semiconductor processing tool based on the plurality of sensor measurements, detect a deviation of at least one signal characteristic of a wireless signal from a pre-configured value, generate a correlation based on the deviation of the at least one signal characteristic of the wireless signal and the presence of the disrupting object, and perform a mitigation action associated with the wireless signal at least partially based on the correlation.

In some embodiments, a method for sensor-assisted signal calibration of a semiconductor processing tool includes decoding a plurality of sensor measurements received from at least one range-finding sensor of a sensor array associated with the semiconductor processing tool. The method further includes detecting a presence of a disrupting object within an access zone of the semiconductor processing tool based on the plurality of sensor measurements. The method further includes detecting a deviation of at least one signal characteristic of a wireless signal from a pre-configured value. The method further includes generating a correlation based on the deviation of the at least one signal characteristic of the wireless signal and the presence of the disrupting object. The method further includes performing a mitigation action associated with the wireless signal at least partially based on the correlation.

In some examples, a system for assisting in the calibration of a wafer-handling robot for a semiconductor processing tool is provided. An example system comprises an autocalibration wafer, described further below, including a substrate sized to be carried by the wafer-handling robot and having a first side that is configured to contact an end effector of the wafer-handling robot when the substrate is carried by the wafer-handling robot, and a plurality of sensors supported by the substrate, each sensor having a downward-facing field of view when the substrate is oriented with the first side facing downwards. The example system further comprises an autocalibration controller, wherein the autocalibration controller is wirelessly connected to each of the plurality of sensors. A time-of-flight (TOF) range-finding sensor is arranged to detect the presence or track movement of a person or object located in an “access zone” of the semiconductor processing tool. A wireless connectivity controller is wirelessly connected to the autocalibration controller and the TOF range-finding sensor and can transmit an instruction to the autocalibration wafer or a component of the semiconductor processing tool. In some examples, feedback from a sensor or wireless device can be sent to one or more other wireless devices in the access zone or wireless environment to optimize communication and/or characterize the zone or environment.

In some examples, the TOF range-finding sensor is a light detection and ranging (LIDAR) sensor, which can include a two-dimensional (2D) LIDAR sensor configured to measure the distance to an object and/or a three-dimensional (3D) LIDAR sensor configured to measure 3D coordinates of an object. A LIDAR sensor operates by emitting pulsed light waves into the area surrounding the sensor. The emitted light waves reflect from the surrounding objects and the environment profiles and return to the sensor. The sensor measures TOF for each pulse to calculate the distance the pulse traveled and generate a measure of the distance to an object (e.g., using a 2D LIDAR sensor) or a measure of the location of objects in a 3D environment (e.g., using a 3D LIDAR sensor).

Some examples include a wireless environment that denotes or includes an area of influence of humans (personnel) and/or objects that can perturb or disrupt wireless communication between wireless devices, such as an autocalibration wafer and a wireless router, or other wireless communication devices, for example. In some examples, a detection system can be used to track or detect personnel and/or objects located between the autocalibration wafer and the wireless router, as well as personnel and/or objects as being detected “not between” wireless devices such as the autocalibration wafer and the wireless router. Counterintuitively, in some examples, personnel or objects “between” the autocalibration wafer and the wireless router can both help and hinder wireless communications. For example, a person or object intentionally (or unintentionally) placed between the autocalibration wafer and wireless router (or other devices) can, in some circumstances, be beneficial in mitigating undesired wireless communications by blocking signals from unnecessary or unwanted devices that would otherwise interfere with communications between necessary or desired devices. In some examples, a wireless environment can be modified to enhance wireless communications between devices.

In this specification, and where the context permits, the terms access zone (e.g., personnel access zone) and wireless environment can be used interchangeably. Viewed broadly, these terms are intended to define or denote an area or region of influence of humans (personnel) and/or objects that can perturb or disrupt wireless communication between wireless devices (e.g., wireless signals passing through such area). A monitored access zone and/or wireless environment may include aspects relating to the detection, measuring, and/or monitoring of objects and personnel (or only one or the other) within the zone or environment. An object may include a portion or part of a semiconductor processing tool or a component. The object may be used directly or indirectly in connection with a semiconductor processing tool.

### BRIEF DESCRIPTION OF THE SEVERAL VIEWS OF THE DRAWINGS

Some embodiments are illustrated by way of example and not limitation in the views of the accompanying drawings, in which:

FIG. 1 is a plan view of an example configuration of a semiconductor processing tool including six process modules;

FIG. 2 depicts a schematic diagram of a semiconductor processing tool in accordance with an embodiment.

FIG. 3 depicts a schematic pictorial diagram of a semiconductor processing tool in accordance with an embodiment.

FIG. 4 depicts an equipment front-end module (EFEM) adjacent to a vacuum transfer module (VTM) in accordance with one embodiment.

FIGS. 5A-5B illustrate aspects of the subject matter in accordance with example embodiments.

FIGS. 6A-6D illustrates further aspects of the subject matter in accordance with example embodiments.

FIG. 7A illustrates a flowchart of a method in accordance with an example embodiment.

FIG. 7B illustrates a flowchart of a method in accordance with an example embodiment.

FIG. 8 is a block diagram illustrating an example of a machine upon which one or more example embodiments may be implemented or by which one or more example embodiments may be controlled.

FIGS. 9-10 illustrate aspects of a wireless environment and a wireless environment controller, according to example embodiments.

### DETAILED DESCRIPTION

The description that follows includes systems, methods, techniques, instruction sequences, and/or computing machine program products that embody illustrative embodiments of the present disclosure. In the following description, numerous specific details are outlined to provide a thorough understanding of example embodiments. It will be evident, however, to one skilled in the art that the present disclosure may be practiced without these specific details. Further areas of applicability of the present disclosure will become apparent from the detailed description, the claims, and the drawings. The detailed description and specific examples are intended for purposes of illustration only and are not intended to limit the scope of this disclosure.

The quantity, position, etc., of substrate processing tools within a fabrication room may be constrained by the room size and each tool's footprint. The footprint of a substrate processing tool is the floor space needed for the proper installation of the substrate processing tool. To maximize floor space usage in a fabrication room, multiple tools may be placed close together. Depending on how close the tools are placed together, wireless signal interference (e.g., noisy wireless signal) within a single tool may occur. In some instances, the presence of disruptive objects in a signal transmission zone of a substrate processing tool can also negatively affect wireless connectivity. Systems and methods according to the principles of the present disclosure provide various configurations of processing tools and sensors to detect and analyze objects potentially interfering with communication signals or the overall signal transmission. In some embodiments, this information can then be used to maximize the wireless connectivity of one or more processing tool components. Some examples include using a range-finding or TOF sensor (or one or more other types of sensors) to detect human or object presence with or without distance measurement for fault analysis. In some examples, the sensor includes a proximity sensor or other object detection sensors that can characterize a wireless environment based on parameters such as wireless signal propagation, wireless signal strength, safe wireless signal receipt, and other factors and/or characterizations. Some examples may include sensors that can detect specific types of materials, such as metal and/or concrete, that impact a wireless signal.

Using a camera or other full-frame image capture/recording device to identify interfering objects is outside the scope of this disclosure. Semiconductor fabrication facilities often prohibit image capturing/video recording in the fabrication room due to the sensitivity of the manufacturing process. In addition, if objects are identified using an image recognition process, extra steps (e.g., image identification, image noise filtering, etc.) may be needed to extract the key parameters (e.g., distance to transmitters) and thus slow down the overall analysis process. The ability to identify quickly and accurately what is the interfering object without intrusively capturing the background environment using image capturing/recording devices is one of the advantages associated with the disclosed techniques.

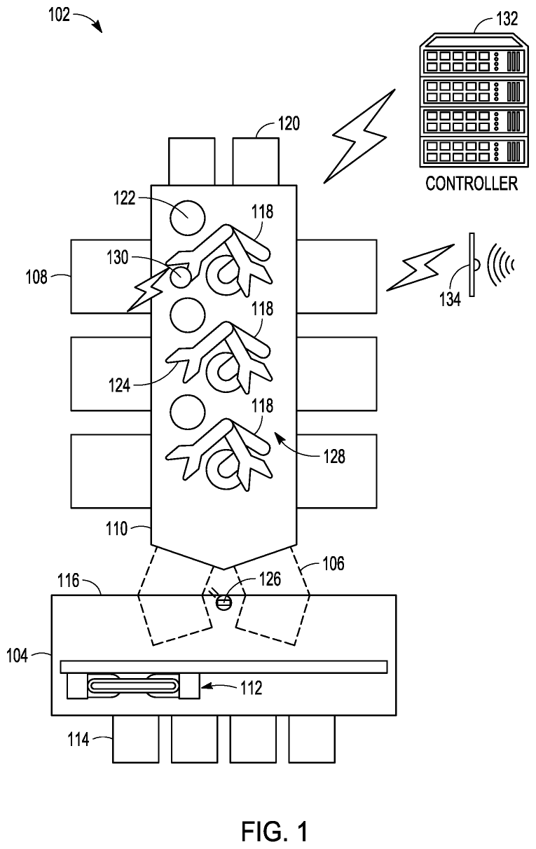

FIG. 1 shows a plan view of an example configuration of a semiconductor processing tool 102 according to the present disclosure. The semiconductor processing tool 102 includes an equipment front-end module (EFEM) 104 configured to accommodate at least a portion of load locks 106. In an example, a transfer robot 112 of the EFEM 104 is arranged closer to loading stations 114 on a front wall (e.g., a first side) than a back wall 116 (e.g., a second side) of the EFEM 104. For example, the loading stations 114 may correspond to front-opening unified pods (FOUPs).

As shown, the semiconductor processing tool 102 includes six process modules 108 (also referred to as PMs). However, other configurations of the semiconductor processing tool 102 may include more than six of the process modules 108. For example, the length of a vacuum transfer module (VTM) 110 may be extended to accommodate additional process modules 108. Similarly, the VTM 110 may include vacuum transfer robots 118, which have various configurations. For example, the semiconductor processing tool 102 includes three vacuum transfer robots 118. In the semiconductor processing tool 102, the vacuum transfer robots 118 are aligned with a center lengthwise axis of the VTM 110. Although shown to have one or two arms, each of the vacuum transfer robots 118 may have configurations including one, two, or more arms. In some examples, the vacuum transfer robot 118 may include two end effectors 124 on each of the arms, as shown in FIG. 1. The semiconductor processing tool 102 may include one or more external storage buffers 120 configured to store one or more substrates between processing stages. In some examples, one or more internal storage buffers 122 may be located within the VTM 110. In some examples, one or more of the external storage buffers 120 and/or internal storage buffers 122 may be replaced with process modules or other components.

In some examples, one or more of the EFEM 104, the load locks 106, the VTM 110, and the process modules 108 may have a stacked configuration, in other words, a high aspect ratio. For example, each of the process modules 108 may correspond to two (or more) process modules 108 in a vertically stacked configuration (i.e., one process module 108 arranged above/below the other), the VTM 110 may correspond to two (or more) VTMs in the vertically stacked configuration, each of the load locks 106 may correspond to two (or more) load locks 106 in the vertically stacked configuration, and each of the loading stations 114 may correspond to two (or more) loading stations 114 in the vertically stacked configuration. The height of the EFEM 104 may be increased to allow the vacuum transfer robots 118 to be raised and lowered to different levels within the EFEM 104 to access multiple levels of the loading stations 114 and the load locks 106.

This high aspect ratio, among other things, of the vertically stacked arrangement can present challenges to establishing and maintaining good wireless connectivity between a wireless router and a wireless device such as an APS, for example, as described further below. Furthermore, personnel access and disruptive foreign objects placed in a path between a wireless router and an APS, for example, in an access zone 128 on a top side or grating above the VTM 110, can negatively interfere with the wireless connectivity and cause faults. Systems and methods according to the principles of the present disclosure provide various configurations of processing tools and at least one sensor 126 to maximize wireless connectivity of processing tool components. In some aspects, the at least one sensor 126 is a TOF sensor. As used herein, the term “time-of-flight sensor” (or “TOF sensor”) indicates a sensor configured with time-of-flight technology, which uses the time it takes light photons to travel between two points to calculate the distance between the two points. Some examples of the at least one sensor 126 include a TOF sensor to detect human or object presence and distance measurement (range finding) for fault analysis, optimization of wireless connectivity, and fine-tuning of substrate processing parameters, such as calibration and substrate placement discussed further below.

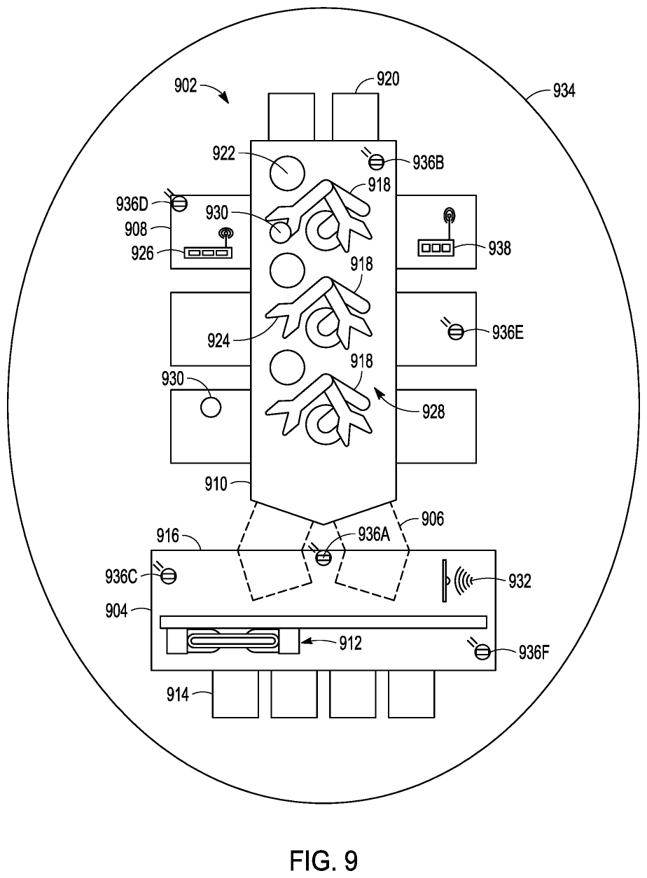

Even though FIG. 1 illustrates the at least one sensor 126 as a single sensor, the disclosure is not limited in this regard and multiple TOF sensors (and/or other types of sensors) can be used as the at least one sensor 126. For example, FIG. 9 illustrates a configuration where multiple sensors are used to detect a disruptive object, assess the object's location and/or movement pattern, assess interference of the object on wireless (or wired) signal communications, and generate a notification of any detected interference and/or perform a mitigation action to reduce or prevent the interference.

In some examples, the at least one sensor 126 is located on the back wall 116 of the EFEM 104 overlooking the VTM 110. In some implementations, a field of view of the at least one sensor 126 is configured and limited to comport with the length of the VTM 110 to avoid the inclusion of extraneous noise or unnecessary data. Semiconductor processing tools utilize wafer-handling robots, such as the vacuum transfer robots 118, to move semiconductor wafers in between various wafer stations, such as the process modules 108 of the semiconductor processing tool 102. Since wafer-handling robots typically pick up semiconductor wafers from below using a blade- or spatula-type end effector (such as the end effectors 124) and the semiconductor wafers are not positively secured to the wafer-handling robot end effector, there is often some small degree of variance in relative positioning between the end effector and the semiconductor wafers placed thereupon. In some examples, variance is caused by the placement accuracy of the robots, tolerancing of all hardware that specifies the location of wafer stations, and changes in positions of those stations with changes in temperature due to thermal expansion. Due to the sensitivity of semiconductor processing operations, it is typical to correct for such variance when placing semiconductor wafers using a wafer-handling robot so that the semiconductor wafers are placed in their respective processing stations within an acceptable tolerance range at a desired location, e.g., generally centered in the processing stations, or concentrically arranged. Modern semiconductor processing tools utilize active wafer-centering (AWC) systems to aid in such wafer placements.

An aspect of the present disclosure includes an autocalibration system, e.g., an APS mentioned above, that may be used in conjunction with an AWC system (or similar apparatus) and/or wafer-handling robot to, among other things, provide for automated teaching of the AWC system and/or the wafer-handling robot for a semiconductor processing tool; such a system may be used for automated teaching of a wafer-handling robot either under vacuum or atmospheric pressure, as the chambers within which the teaching occurs may be sealed as they would be during normal semiconductor processing operations. In some examples, AWC is a method of measuring deviations of wafer location in a given (x, y) position concerning a robot position. It does not necessarily inform about the location of wafer stations where wafers are placed. In some examples, APS teaches the robot where the wafer stations are. APS does not inform AWC.

The automated teaching may thus occur wirelessly or at least involve wireless communications, given the sealed access. Such an auto-calibration system may also allow for various aspects of component or wafer placement to be evaluated and/or corrected, as needed, to comply with process requirements. The autocalibration system may also be used to guide the placement of edge rings, which are nominally annular structures that have an inner diameter that is typically sized just slightly larger (or smaller, in some cases) than the outer diameter of a semiconductor processing wafer, thereby effectively “extending” the diameter of the semiconductor wafer during processing. Edge rings have the effect of causing any “edge effects” that might degrade the on-wafer process, resulting in uniformity occurring on the outer edge of the edge ring (where wafer uniformity is largely unaffected) rather than on the semiconductor wafer itself.

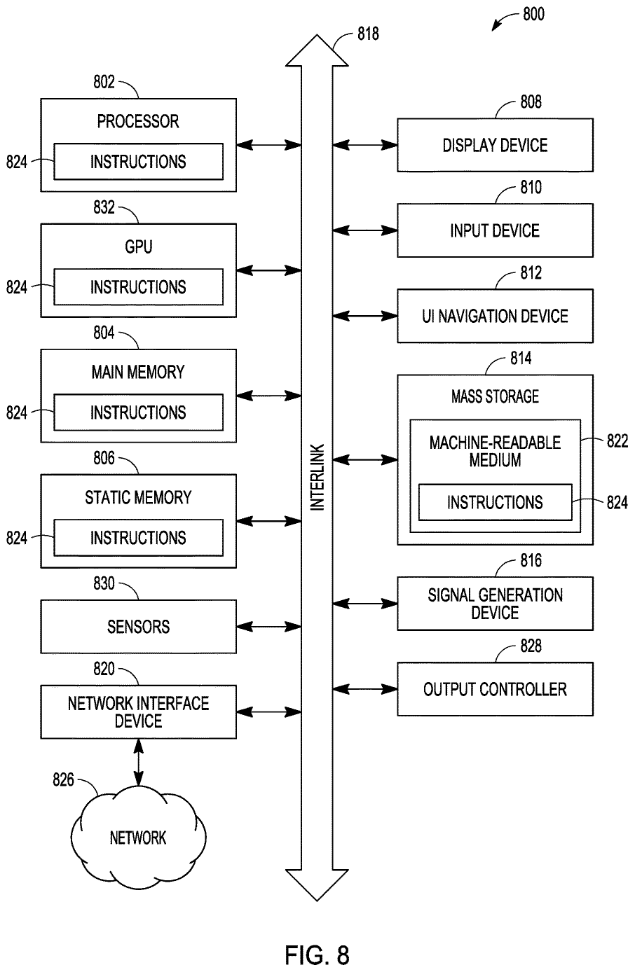

Central to the autocalibration system is an auto-calibration wafer, which may also be referred to as an APS wafer (such as the APS wafer 130, FIG. 1), that may collect a large amount of information from a variety of on-board sensors; this allows the autocalibration wafer to be used as part of an entirely automated teaching process. The onboard sensors of the APS wafer 130 communicate wirelessly with one or more of a controller (such as the controller 132, FIG. 1, and/or the controller 800, FIG. 8) and/or a wireless router 134, or a process module 108, to relay signals and data. Such an autocalibration wafer may be used, for example, to perform diagnostic evaluations of components in a semiconductor processing tool, as well as to obtain information that allows the operation of the semiconductor processing tool to be adjusted to enhance wafer-processing performance.

Generally speaking, the autocalibration wafer for a particular semiconductor processing tool may have a size and shape similar to that of a wafer and/or edge ring that the semiconductor processing tool is configured to process, thereby allowing the autocalibration wafer (e.g., APS wafer 130) to be transported by a wafer-handling robot (see FIG. 1) of the semiconductor processing tool in generally the same manner as the wafer-handling robot transports semiconductor wafers during processing. Thus, the autocalibration wafer may be sized to have a maximum height and diameter that are less than the most minor vertical and horizontal clearances of passages of the semiconductor processing tool through which the wafer-handling robot may transport wafers.

As noted above, the autocalibration wafer may include a variety of sensors. The number and type of sensors may vary depending on the particular functionalities provided by the autocalibration wafer. It will be understood that an autocalibration wafer may be configured to provide any, some, or all of the sensors/functionalities discussed herein.

In addition to the various sensors that the autocalibration wafer may include, the autocalibration wafer may also include various components for controlling and obtaining data from those sensors, communicating wirelessly with other components (such as a controller 132 of the semiconductor processing tool 102, and/or the wireless router 134, and/or a process module 108, FIG. 1), and/or storing and/or manipulating the data collected from the sensors. Such autocalibration wafers may thus be linked or wirelessly to a controller or router of a semiconductor processing tool, introduced into the semiconductor processing tool, and then, through actions caused by one or both of a controller (or controllers) of the autocalibration wafer and the controller (or controllers) of the semiconductor processing tool, caused to perform various sensing and data collection operations during various phases of a calibration routine or placement routine performed by the semiconductor processing tool. As will be apparent from the examples discussed in more detail below, such a calibration routine or placement routine may be performed by the semiconductor processing tool with little or no human oversight.

A first controller carried on the autocalibration wafer may also be communicatively connected with a first wireless communications interface, e.g., a Wi-Fi, Bluetooth, or other wireless communications interface, so that commands and/or data may be sent from and/or to the first controller, and thus the auto-calibration wafer. For example, a semiconductor processing tool that interfaces with the autocalibration wafer may include a second controller having one or more second processors and one or more second memories. The second controller may be communicatively connected with a second wireless communications interface that may, in turn, be configured to interface with the first wireless communications interface of the autocalibration wafer. Thus, the autocalibration wafer may be able to wirelessly communicate with the semiconductor processing tool, allowing information, commands, and other data to be transmitted between the autocalibration wafer and the semiconductor processing tool.

Any interruption of the wireless connection between the wirelessly connected components and the autocalibration wafer can have significant adverse effects. For example, personnel presence and disruptive foreign objects placed in a path between the semiconductor processing tool and an autocalibration wafer can interfere with wireless connectivity and cause calibration and placement faults. Embodiments of the present disclosure utilize one or more object detection sensors and analytic systems to gain insights into the cause of signal/connectivity interference. Object detection and diagnostics based on such detection provided by embodiments of the present disclosure enable an informed analysis of faults, leading to enhanced calibration and placement routines.

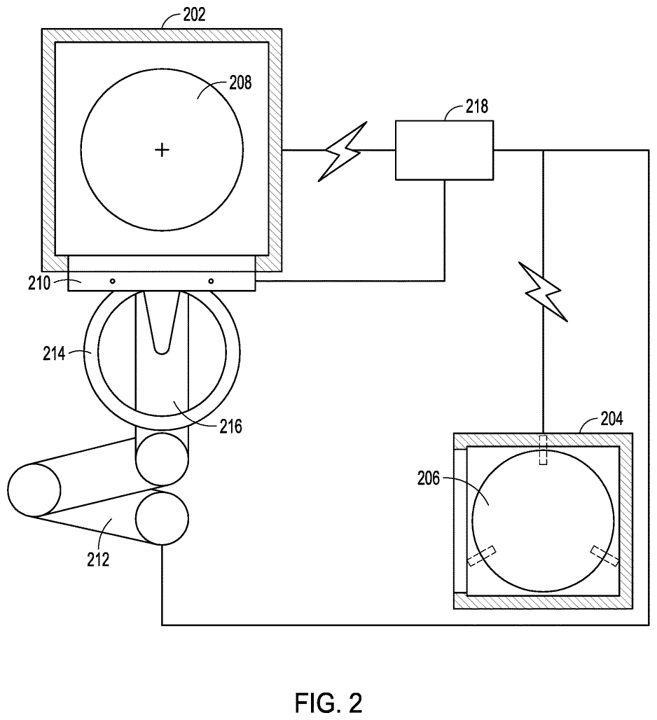

FIG. 2 depicts a schematic of a semiconductor processing tool using an autocalibration wafer. In FIG. 2, a portion of a semiconductor processing tool, such as the semiconductor processing tool 102 of FIG. 1, is shown. The depicted portion of the semiconductor processing tool includes two wafer stations, a first wafer station 202 and a second wafer station 204. However, the tool may include further wafer stations as well. Each wafer station corresponds with a location in which one or more wafers may be placed during various operations performed by the semiconductor processing tool. Wafer stations may, for example, and without limitation, exist within a process chamber or process chambers of the tool (e.g., in the process modules 108), on a VTM (e.g., the VTM 110), in buffers used to store wafers before or after processing (e.g., the external storage buffers 120, or the internal storage buffers 122), in airlocks or load locks (e.g., the load locks 106) that allow wafers to be transferred between environments at different pressures, load ports (e.g., at loading stations 114), in front-opening unified pods (FOUPs) that may be docked to a load port, and so forth.

In FIG. 2, the first wafer station 202 is provided by a semiconductor processing chamber; in contrast, the second wafer station 204 is provided by a docking station that is dedicated to the storage of an autocalibration wafer 206 (although such a dedicated docking station may not be included in some implementations). The docking station may have features (not shown) for charging the autocalibration wafer 206 or otherwise be configured to interface with various aspects of the autocalibration wafer 206. In some implementations, the second wafer station 204 (docking station) may be located in a VTM (e.g., VTM 110) (or be attached to it) to allow it to be accessed by a wafer-handling robot (e.g., a vacuum transfer robot 118) in the VTM which may then be trained using the autocalibration wafer 206. In other implementations, the second wafer station 204 (docking station) may be located in an EFEM (e.g., EFEM 104) or other atmospheric or near-atmospheric pressure location, in which case the autocalibration wafer 206 may first be retrieved using a wafer-handling robot located in the EFEM and then transferred to another wafer handling robot located in a VTM.

The first wafer station 202 may have an associated wafer support 208 (no wafer support is shown in the second wafer station 204, but it may also have a wafer support that may receive the autocalibration wafer 206 when placed therein). In some instances, a wafer station may be associated with an AWC system 210, which may allow measurements of wafer center locations to be obtained as wafers are introduced to or removed from an associated wafer station. In this example, the AWC system 210 is associated with the first wafer station 202 and includes two vertically oriented optical beam sensors (represented by the dots within the AWC system 210) that may detect when an edge of a wafer crosses through either optical beam. The AWC system 210 may be used to determine the center location of a wafer supported by an end effector (e.g., the end effector 124) of a wafer-handling robot (e.g., a vacuum transfer robot 118) of the tool (e.g., the semiconductor processing tool 102) relative to a particular, known frame of reference, thereby allowing a determination to be made as to any positioning corrections that may need to be made before placing the wafer at a desired location. As shown in FIG. 2, the wafer-handling robot 212 is supporting an edge ring 214 on the end effector 216 in preparation for placing the edge ring 214 on the wafer support 208. The autocalibration wafer 206, in the interim, is in temporary storage in the second wafer station 204. Various calibrations, such as off-centeredness and wafer placement techniques, may be practiced using wirelessly connected components, such as the autocalibration wafer 206 and controller 218 of a substrate processing tool, as discussed above.

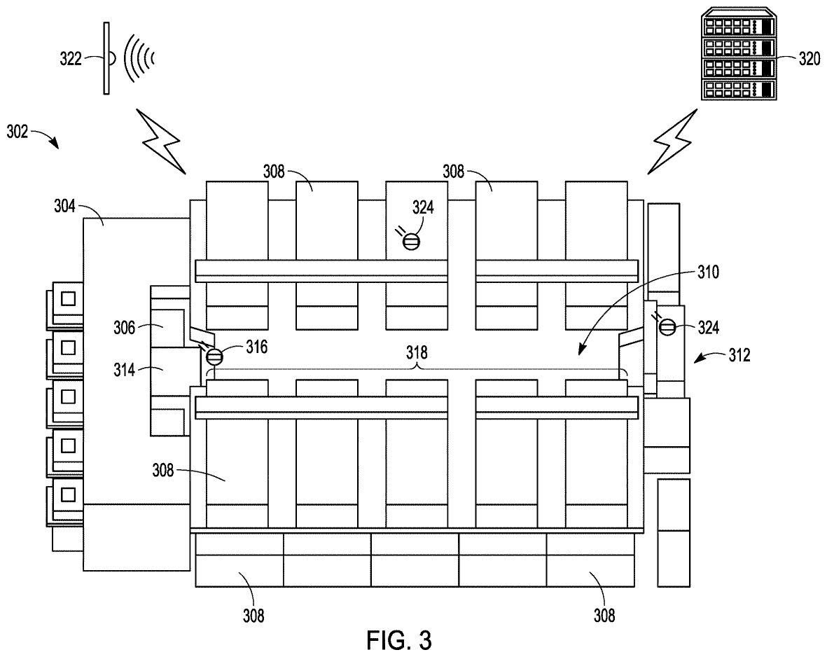

FIG. 3 depicts a schematic pictorial diagram of a semiconductor processing tool 302 in accordance with an embodiment. The semiconductor processing tool 302 includes an EFEM 304 and load locks 306 located between EFEM 304 and VTM 310. VTM 310 houses wafer-handling robots (not visible beneath the top side or housing of the VTM 310 shown in FIG. 3). The wafer-handling robots may include vacuum transfer robots 118 (FIG. 1) or wafer-handling robots 212 (FIG. 2), for example. Other wafer-handling robots are possible. The semiconductor processing tool 302 includes loading stations 312.

As shown, the semiconductor processing tool 302 includes ten stacked process modules 308. However, other configurations of the semiconductor processing tool 302 may include more or less than ten of the stacked process modules 308. For example, the length of the VTM 310 may be extended to accommodate additional stacked process modules 308.

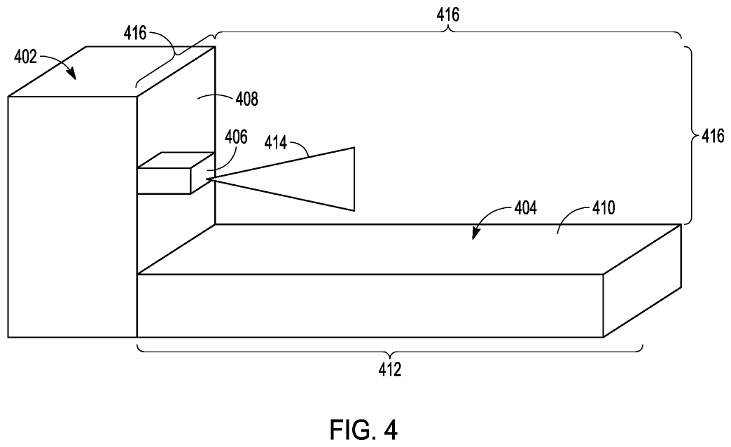

The EFEM 304 has a back wall 314. In the illustrated example, at least one sensor 316 (e.g., a TOF sensor) is mounted on the back wall 314 to oversee and monitor an access zone 318 situated above the housing of the VTM 310. The access zone 318 may be a three-dimensional access zone defined, for example, by the dimensions indicated by the brackets in FIG. 4. In other examples, the access zone 318 may be defined by a plane, a line, or a specific point-location associated with the semiconductor processing tool 302, or a stacked process module 308, or other components of the semiconductor processing tool 302. The at least one sensor 316 may be provided with one or more fixed or movable locations, for example, located at the alternate sensor locations 324 as shown in FIG. 3, although other locations are possible in connection with wireless connectivity optimization, discussed further below. The at least one sensor 316 may include an array of sensors provided at one or several locations associated with the semiconductor processing tool 302 and/or a component thereof. The array of sensors may include a plurality of wirelessly interconnected time-of-flight sensors, each located at a different location within, on, or around the semiconductor processing tool 302 or a component thereof (e.g., as illustrated in FIG. 9). In some examples, the at least one sensor 316 is wirelessly connected to a wireless connectivity controller 320 and/or to at least one remote wireless router 322. In some embodiments, the at least one sensor 316 includes an array of sensors connected to one another and/or to a controller via a physical signal transmitter such as an electrical wire.

As shown, one or more of the EFEM 304, the load locks 306, the VTM 310, and the stacked process modules 308 may have a stacked configuration defining a high aspect ratio and at least part of the access zone 318. For example, each of the stacked process modules 308 may correspond to two (or more) stacked process modules 308 in a vertically stacked configuration (i.e., one stacked process module 308 arranged above/below the other), the VTM 310 may correspond to two (or more) VTMs 310 in the vertically stacked configuration, each of the load locks 306 may correspond to two (or more) load locks 306 in the vertically stacked configuration, and each of the loading stations 312 may correspond to two (or more) loading stations 312 in the vertically stacked configuration. The height of the EFEM 304 may be increased to allow the wafer-handling robots in the VTM 310 to be raised and lowered to different levels to access multiple levels of the loading stations 312 and the load locks 306.

FIG. 4 depicts an EFEM 402 located adjacent to a VTM 404 in an example configuration of a semiconductor processing tool. At least one sensor 406 is mounted to a back wall 408 of the EFEM 402. Other mounting locations of the at least one sensor 406 on or within the semiconductor processing tool are possible. The at least one sensor 406 has a field of view 414. The at least one sensor 406 is located such that the field of view 414 of at least one sensor 406 can oversee intrusions of personnel and/or objects into an access zone 416 located above the VTM 404. An assigned dimension (e.g., length, width, height) or areal size of the field of view 414 may correspond with a dimension of the EFEM 402 and/or a dimension of the VTM 404 (for example, the VTM length 412 of the VTM 404), and/or a dimension of the access zone 416, and or an aspect of the tool density discussed above. In some implementations, a field of view 414 of the at least one sensor 406 is configured and limited to comport with a dimension of the VTM 404 and/or the access zone 416 to avoid the inclusion of extraneous noise or gathering unnecessary data from an irrelevant zone.

In some implementations, the at least one sensor 406 (hereinafter collectively including the at least one sensor 126 and the at least one sensor 316) has range finding as well as detection capabilities. The at least one sensor 406 may include a LIDAR sensor. The at least one sensor 406 can determine distances between a detected person and/or object in the field of view 414 and the at least one sensor 406. Using algorithms, the at least one sensor 406 can, in some implementations, determine distances between a detected person or object and a wall or feature of an adjacent component such as the EFEM 402 or VTM 404 (or other components) located in the field of view 414, or defining or enclosing the access zone 416. The at least one sensor 406 may be included in an array of sensors, or provided as one of a plurality or interconnected series of time sensors surrounding access zone 416. In some embodiments, the at least one sensor 406 includes an array of multiple TOF sensors that can provide mosaicked or combined fields of view 414. Given certain drawbacks, the use of a camera as a sensor in the wireless connectivity methods described herein is outside the scope of this disclosure.

In some aspects, at least one sensor 406 is a 2D LIDAR sensor, which is configured to measure the distance to an object (e.g., a single distance measurement). In some embodiments, at least one sensor 406 is a 3D LIDAR sensor, which is configured to measure the 3D coordinates of an object (e.g., spatial coordinates in 3D coordinate systems including x, y, and z axes). In some examples, the at least one sensor 406 is located on a semiconductor processing tool or module to detect and monitor, using range finding and distance measurement, a human or object presence in a specified field of view. The at least one sensor 406 can continuously (or periodically) record detection timestamps and track the detected human or object location relative to the sensor while the human or object is in the field of view. The information enables the semiconductor processing tool to obtain information such as when and where service personnel or an object has entered a specific location (such as the access zone 416), how long they were there, the direction of movement, and what part of the semiconductor processing tool or component was accessed. Data captured and generated by the at least one sensor 406 can be used to generate analytics relating to personnel and/or object access to and movement within the field of view 414 or the monitored access zone 416. In aspects when the at least one sensor 406 is a 2D LIDAR sensor, only distance to the object is measured. In some aspects, at least one sensor 406 includes multiple 2D LIDAR sensors placed in the vicinity of access zone 416, which can be used to determine the location of an object placed within access zone 416 (e.g., spatial coordinates of the object). In some aspects, the at least one sensor 406 can be a 3D LIDAR sensor, which can be used to determine the spatial coordinates of the object placed within access zone 416.

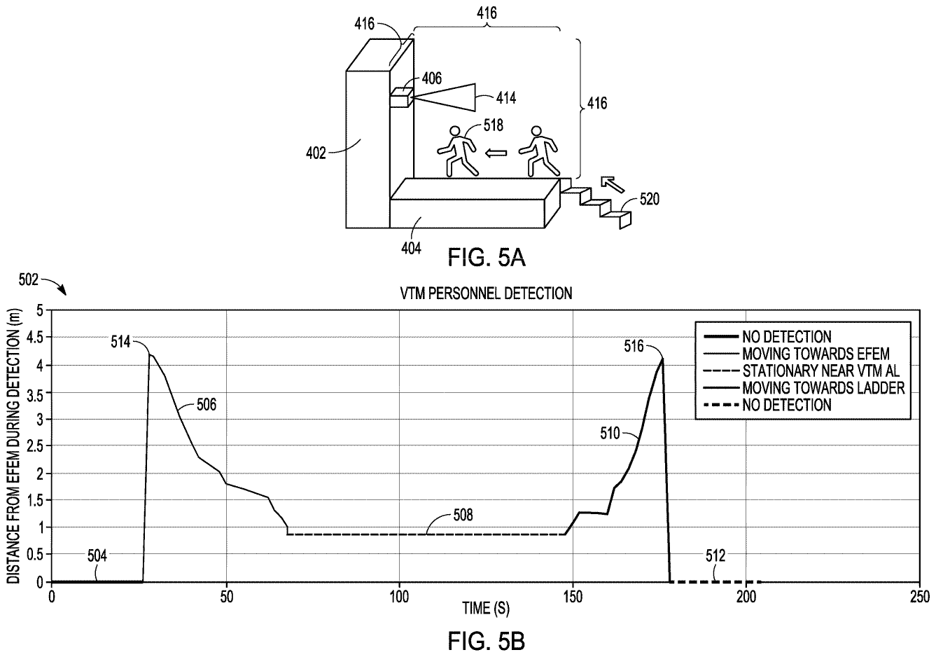

For example, concerning FIGS. 5A-5B, the movements of a person 518 entering a monitored access zone 416 via a ladder 520 (for example) can be tracked and recorded. An output of at least one sensor 406 can be used to detect the presence and track movements and associated distances (or positions) of person 518 entering and moving in access zone 416, as represented in the example personnel detection graph 502 of FIG. 5B. The y-axis of the personnel detection graph 502 represents a detected distance of person 518 from the EFEM 402 in an access zone 416 above a VTM 404. Other access zones defined by other regions or components of substrate processing are possible. Corresponding fields of view 414 may be tailored or configured to oversee such access zones accordingly. The x-axis of the personnel detection graph 502 represents time in access zone 416 and indicates periods for detected locations of person 518 entering, moving or remaining stationary within and/or exiting access zone 416 monitored by at least one sensor 406.

In graph zone 504, there is no detection of the presence or movement of person 518. At graph point 514, the presence of person 518 in the monitored access zone 416 is detected. In graph zone 506, person 518 is tracked by the at least one sensor 406 as moving towards the EFEM 402. In graph zone 508, person 518 is stationary (no movement is detected). The range-finding capability of the at least one sensor 406 is used to detect that the person 518 is positioned close to the EFEM 402 while stationary, for example. Other range-finding and position-detection modes or examples are possible. In graph zone 510, person 518 is detected as moving again, but this time towards ladder 520. At graph point 516 (corresponding in y-value, i.e., distance from EFEM 402, as graph point 514), the person 518 is detected as leaving the access zone 416. In graph zone 512, no further presence or movement is detected. In aspects when at least one sensor 406 is a single 2D LIDAR sensor, only a single person in the FoV of the sensor is detected. However, if the at least one sensor 406 includes multiple 2D LIDAR sensors (e.g., placed across each other around the perimeter of the access zone 416, then multiple persons can be detected when entering the access zone 416. Alternatively, if at least one sensor 406 includes a 3D LIDAR sensor, then multiple persons can also be detected when entering access zone 416.

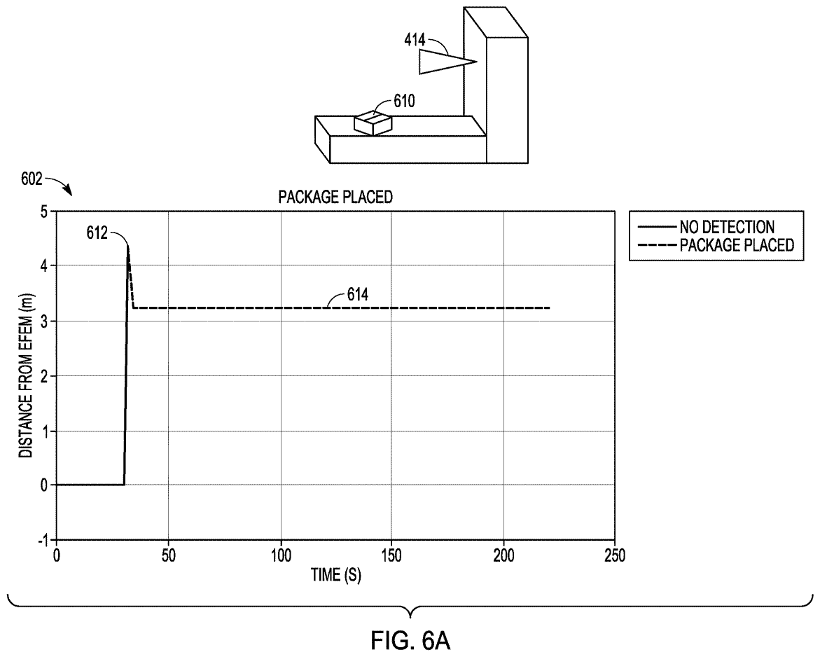

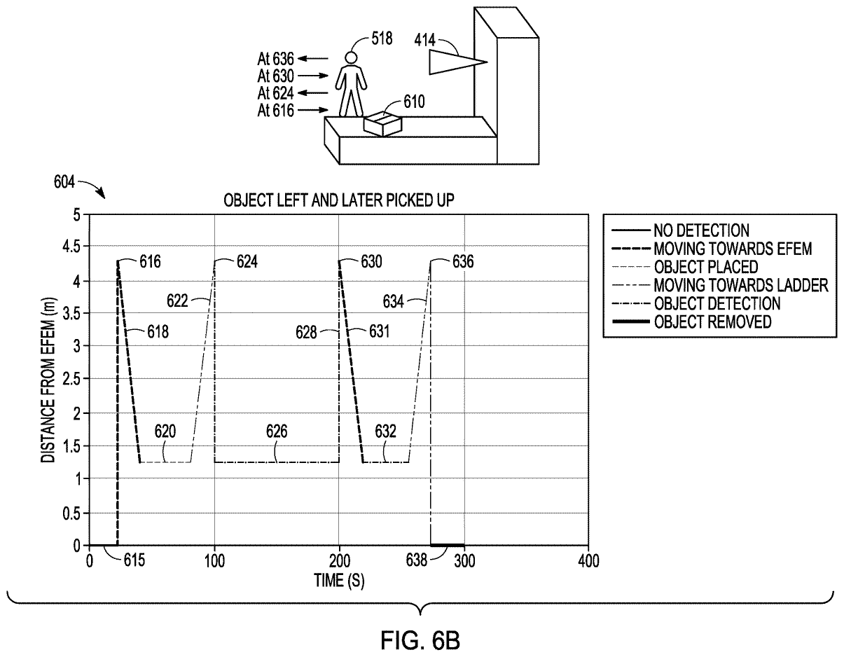

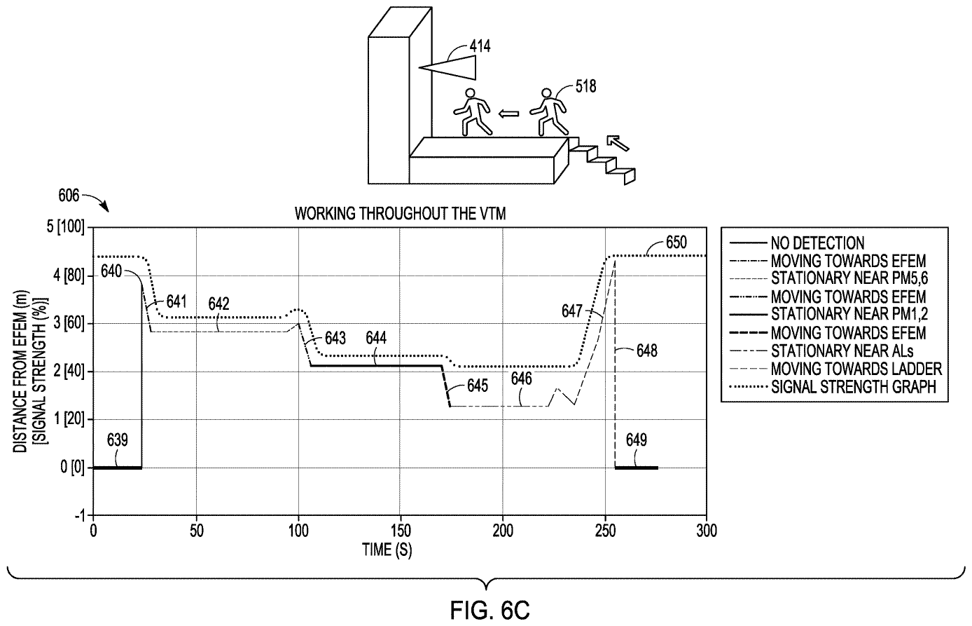

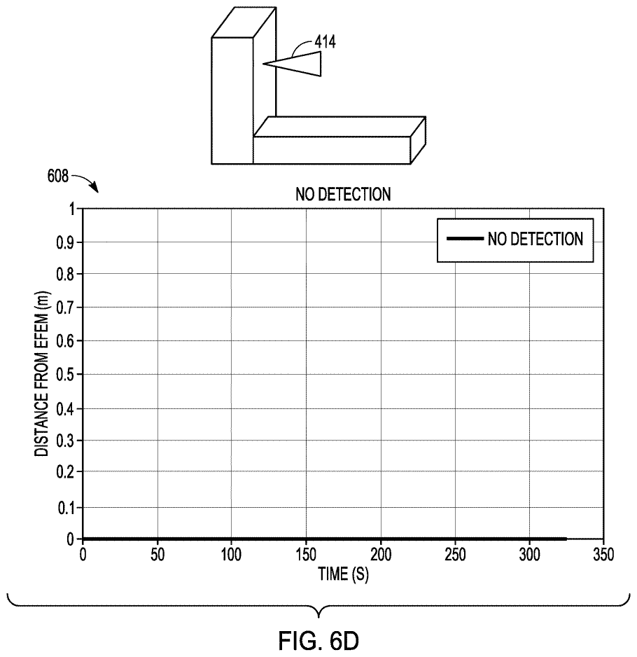

Further detection examples are provided in FIGS. 6A-6D. In each depicted graph in these views (i.e., the disruptive object detection graph 602, the disruptive object detection graph 604, the disruptive object detection graph 606, and the “all quiet” graph 608, respectively), the y-axis represents a detected distance of a person 518 or an object 610 from an EFEM 402 in an access zone 416 above a VTM 404. The x-axis represents time in access zone 416 (e.g., as detected by the at least one sensor 406) and indicates periods for detected locations of person 518 or object 610 entering, moving, or remaining stationary within the access zone 416, and/or exiting the access zone 416 monitored by the at least one sensor 406. In aspects when the at least one sensor 406 is a 2D LIDAR sensor, distance to the person 518 or the object 610 can be determined. In aspects when the at least one sensor 406 includes multiple 2D LIDAR sensors or a single 3D LIDAR sensor, spatial coordinates of the person 518 or the object 610 can be determined. In some aspects, the use of multiple 2D LIDAR sensors or a 3D LIDAR sensor as the at least one sensor 406 can ensure object detection coverage for the entire access zone 416 without the existence of any dead zones.

In the disruptive object detection graph 602, object 610 (such as a package, a box, or a maintenance tool) is placed in access zone 416. Graph point 612 indicates that the presence of object 610 is detected by the at least one sensor 406. In graph zone 614, the flat line of the disruptive object detection graph 602 indicates no further movement is detected. Object 610 is stationary. The range finding capabilities of at least one sensor 406 determine that object 610 remains stationary for a period (for example, between the time points at approximately 30-225 seconds, given by the x-axis values) at a distance of approximately 3.25 meters from the EFEM 402 (given by the y-axis value). In some examples, the extended stationary nature of object 610 (represented, for example, by the relatively long flat line in the disruptive object detection graph 602) may serve to distinguish object 610 from a moving person 518 potentially present in access zone 416.

Similarly, in the disruptive object detection graph 604 (FIG. 6B), no presence or movement of a disruptive object is detected in graph zone 615. A person 518 (with object 610) entering access zone 416 is detected, as indicated by graph point 616. In graph zone 618, person 518 moves to a location approximately 1.4 meters from the EFEM 402. The rapidity of the movement may be indicated, for example, by the short period yielded by the x-axis values. The location information is represented by the values reflected on the y-axis. The data on which such disruptive object (e.g., object and/or person) tracing and analysis is based is captured and generated by at least one sensor 406. In graph zone 620, the disruptive object (e.g., person 518) remains stationary, and in graph zone 622, it leaves the surface of VTM 404 and moves away from the EFEM 402 side (without picking up object 610, which can be a tool). At graph point 624, the presence of object 610 is detected (which was left by person 518 before leaving the surface of VTM 404). Object 610 remains stationary for the duration of graph zone 626. The vertical graph portion 628 indicates the detection of person 518 (e.g., at graph point 630) (e.g., person 518 has returned to pick up object 610). In graph zone 631, person 518 moves to the exact location where object 610 was previously left (e.g., graph zone 626 and graph zone 632 are associated with the same distance to EFEM 402). In graph zone 632, the disruptive object (e.g., person 518 with object 610) remains stationary. In graph zone 634, the disruptive object (e.g., person 518 with object 610) leaves the surface of VTM 404 and moves away from the EFEM 402 side (without picking up object 610, which can be a tool). At graph point 636, the disruptive object (e.g., person 518 with object 610) is detected as leaving access zone 416. In graph zone 638, no further presence or movement is detected.

In the disruptive object detection graph 606 (FIG. 6C), in graph zone 639, no presence or movement of person 518 or object 610 is initially detected. At graph point 640, the presence of person 518 (in this example) is detected entering access zone 416. Graph zone 641 indicates that person 518 moved towards the EFEM 402 from a location approximately 4 meters to 3 meters away from the EFEM 402 (given by y-axis values). The graph zone 642 indicates (or represents) that person 518 remains stationary from 25-100 seconds (i.e., a period of 75 seconds). Graph zone 643 indicates that person 518 moved towards the EFEM 402 from a location 3 meters to 2 meters away from the EFEM 402 (given by y-axis values). Graph zone 644 indicates the person remained at the 2-meter location (for example, adjacent to a first stacked process module 308) for the period indicated on the x-axis. Graph zone 645 indicates that person 518 again moved closer to the EFEM 402 to another location approximately 1.25 meters from the EFEM 402 (for example, adjacent to a second stacked process module 308) and remained stationary there for the duration of graph zone 646. In graph zone 647, person 518 moves towards ladder 520, and in graph zone 648 exits access zone 416. In graph zone 649, no further presence is detected.

FIG. 6C further includes a wireless signal strength graph 650, which correlates to the movement of the disruptive object, as indicated by the disruptive object detection graph 606. More specifically, a wireless transceiver (not illustrated in FIG. 6C) can be located within an internal space of the EFEM 402 (e.g., in the vicinity of at least one sensor 406). Wireless signals transmitted by such transceiver (or communicated for reception by the transceiver) within access zone 416 have a signal strength that is proportional to the proximity of a disruptive object to the EFEM 402. As illustrated by graph 650, the wireless signal strength decreases as the disruptive object moves closer to EFEM 402, and the wireless signal strength increases as the disruptive object moves away from EFEM 402 and leaves access zone 416. In some embodiments, the wireless signal strength (or one or more other signal characteristics of wireless signals traversing the access zone) can be monitored periodically (e.g., while a disruptive object is detected as stationary or moving within the access zone using at least one sensor 406). A mitigation action can be performed based on the detected wireless signal strength. For example, suppose the signal strength falls below a first threshold. In that case, the transceiver can be instructed to increase transmission power or adjust the signal propagation path (e.g., by switching the antennas or changing the antenna panel directionality). Suppose the signal strength further deteriorates and falls below a second threshold. In that case, one or more functions of the substrate processing tool can be suspended until the signal strength increases to an optimal level or the disrupting object is no longer detected. In some aspects, the mitigation action can include generating a notification of the detected deviation of the signal characteristic.

An “all quiet” situation may be represented by graph 608 (FIG. 6D), for example. No disruptive object (e.g., person 518 or object 610) is detected by at least one sensor 406 as entering, moving, or remaining stationary within or leaving access zone 416.

In some examples, the detected presence, locations, and/or movements of the disruptive object (e.g., person 518 or object 610) in access zone 416 may be correlated with detected faults in calibration or placement routines in the semiconductor processing tools, as described above. For example, a timestamp of a detected presence, location, or movement may be matched with a time stamp of a fault in calibration, substrate placement, and/or a breakdown in wireless connectivity. Other correlations or matches with such faults, or other types of faults, are possible. Some examples use captured and correlated data to enable optimization and fine-tuning of selected parameters relating to tool calibration, substrate placement, and wireless connectivity in training a machine-learned model or “teaching” a robot, AWC, or APS, for example.

Some correlation examples include wireless connectivity parameters, such as a wireless frequency, a wireless channel, a wireless signal strength, a wireless coverage area, and a wireless signal dead zone. The wireless connectivity parameters, or at least an optimization or measurement thereof, are in some examples correlated with a detected time, date, presence, duration, location, or movement of a person or object within an access zone (such as the access zone 128, and/or the access zone 318, and/or the access zone 416). The correlations may be made, for example, by the wireless connectivity controller 320, FIG. 3). In some examples, a sensor, and/or a wireless connectivity controller, and/or a wireless router are tunable or configurable to adjust a value of a wireless connectivity parameter in real-time.

The wireless connectivity controller 320 may communicate with and source data from one or more sensors (such as at least one sensor 126, and/or at least one sensor 316, and/or at least one sensor 406), The wireless connectivity controller 320 may also communicate with and/or source data via one or more wireless routers (such as the wireless router 134 or at least one remote wireless router 322). The wireless connectivity controller 320 may also communicate and source data from other controllers (such as controller 218 and/or controller 800 (FIG. 8). These communications and data sourcing may be made synchronously or asynchronously with the associated components in the course of outputting wireless connectivity results, wireless connectivity analysis, enabling an optimization or at least improvement of wireless connectivity parameters, correlations, recommendations, and/or other outputs.

In some examples, the wireless connectivity controller 320 makes correlations between a wireless connectivity parameter and the location of a sensor (relating, for example, to the location of at least one sensor 126, and/or at least one sensor 316, and/or the at least one sensor 406). In some examples, the wireless connectivity controller 320 makes correlations between a wireless connectivity parameter and a location or configuration of a semiconductor processing tool (such as the semiconductor processing tool 102 and/or the semiconductor processing tool 302). In some examples, the wireless connectivity controller 320 makes correlations between a wireless connectivity parameter and a location or configuration of an EFEM (such as the EFEM 104, and/or EFEM 304, and/or EFEM 402). In some examples, the wireless connectivity controller 320 makes correlations between a wireless connectivity parameter and a location or configuration of a VTM (such as the VTM 110,/VTM 310, and/or the VTM 404).

In some embodiments, the disclosed functionalities can be configured and performed by one or more additional controllers that work together with (or instead of) the wireless connectivity controller 320. Such one or more additional controllers can include a system controller of the semiconductor processing tool 302 or an off-the-tool controller (e.g., a field engineer's computing device such as a tablet or smartphone).

In some examples, concerning FIG. 1, the wireless connectivity controller 320 makes correlations between a wireless connectivity parameter and a location or configuration of another component or a semiconductor processing tool such as, but not limited to, a load lock 106, a process module 108, a transfer robot 112, a loading station 114, a back wall 116, a vacuum transfer robot 118, an external storage buffer 120, an internal storage buffer 122, an end effector 124, an APS wafer 130, a controller 132, and a wireless router 134.

In some examples, concerning FIG. 2, the wireless connectivity controller 320 makes correlations between a wireless connectivity parameter and a location or configuration of another component or a semiconductor processing tool such as, but not limited to a first wafer station 202, a second wafer station 204, an autocalibration wafer 206, wafer support 208, an AWC system 210, a wafer-handling robot 212, an edge ring 214, an end effector 216, and a controller 218.

In some examples, concerning FIG. 3, the wireless connectivity controller 320 makes correlations between a wireless connectivity parameter and a location or configuration of another component or a semiconductor processing tool such as, but not limited to, a load lock 306, a stacked process module 308, a loading station 312, a back wall 314, at least one sensor 316, an access zone 318, at least one remote wireless router 322, and an alternate sensor location 324.

n some examples, concerning FIG. 4, the wireless connectivity controller 320 makes correlations between a wireless connectivity parameter and a location or configuration of another component or a semiconductor processing tool such as, but not limited to at least one sensor 406, a back wall 408, a top side 410, a VTM length 412, a field of view 414, and an access zone 416.

In some examples, the wireless connectivity controller 320 makes correlations between a wireless connectivity parameter and other aspects including, but not limited to, a tool footprint, a tool spacing, a tool pitch, a tool density of a fabrication room, a number or location of substrate processing tools and/or process modules per unit area of a fabrication room, an external wireless device (such as a smartphone or laptop carried by service personnel), and an external presence of human personnel and/or other disruptive objects. In some examples, an analysis of the wireless connectivity data captured and processed by a sensor and a wireless connectivity controller, including the generating of one or more correlations as discussed above, informs a reconfiguration or reorientation of a semiconductor processing tool or a component thereof, to maximize output or routine of the semiconductor processing tool or a component thereof. A routine may include a calibration or a wafer placement, as discussed above.

A reoriented or reconfigured component may include any one or more of the components and correlations discussed above and/or further described in connection with the accompanying figures. In some examples, a tool or component reconfiguration or reorientation is made, and the correlations are “run again” to detect an improvement in one or more wireless connectivity parameters. Based on such an analysis, a wireless connectivity parameter may be changed or affected to effect an improvement or change in another wireless connectivity parameter. The “rerun” correlations may form part of a machine-learning process to train a machine-learned model that communicates, for example, with a wireless connectivity controller 320 to process and/or provide feedback informing a real-time reorientation or reconfiguration of a tool component to improve or maximize a wireless connectivity parameter, or the efficiency or accuracy of a calibration, processing, or placement routine. For example, based on data captured by a sensor and processed by a wireless connectivity controller, the height or location of a process module may be reconfigured to maximize the signal strength of a wireless signal generally sent to or received by an access zone, or sent explicitly to or received by a wafer-handling robot or a calibration tool. Other examples are possible.

In further aspects, a field of view 414 of at least one sensor 406 may be configured to be less than, equal to, or exceed a VTM length 412. Other settings of the field of view are possible. In some examples, a field of view 414 is configured to equal a VTM length 412 so that potential (or actual) detections of a person 518 or object 610 by at least one sensor 406 outside the field of view 414 are not reported to the wireless connectivity controller 320. Only detections within the field of view 414 are reported. This field-of-view configuration can reduce noise and improve the accuracy of correlations based on a tailored collection of data. In some examples, for ease of operation and simplification, only a single aspect, such as a length or component dimension, is used to determine or establish a field of view 414 of a sensor. This may prevent the need to set up sensor angles and special sensor mountings. In other examples, the aspects are more complicated and may generate more insightful wireless connectivity data and sophisticated correlations. In some examples, a sensor mounting or field of view is adjustable in use after installation and commissioning and/or is retrofittable or adjustable. For example, default sensor mountings and settings may be provided by a semiconductor processing tool supplier and then changed or modified by a customer or semiconductor device maker after the supply and installation of the tool to suit various and/or different manufacturing processes and techniques. In some examples, one or more sensors may be stationarily mounted (i.e., the sensing direction cannot be tilted) to a mounting connector or on a slider. In some examples, one or more sensors may be mounted via a ball-and-socket joint to allow changes to the sensing direction (i.e., the sensing direction can be tilted).

In some examples, for instance, including a LIDAR sensor, a field of view is cone-shaped. Some examples include a narrow 4° field of view. In some examples, the resolution of a field of view is adjustable in real-time. In some examples, a LIDAR sensor discussed herein can be configured to detect a 12-inch by 12-inch package on the floor of an access zone above a VTM.

Present examples exclude the use of image-capturing cameras as a “sensor” in the wireless connectivity techniques described herein. For reasons of privacy and/or confidentiality, some tool operators disallow the use of such cameras in a fab, particularly cameras pointing externally at areas around a semiconductor processing tool. The use of sensors conveniently and adequately meets this need and can capture targeted, relevant wireless connectivity data (such as a person/object's presence, distance, and or ranges) without the need to capture extraneous images or other unnecessary information. Conventional cameras are also typically not sufficiently discriminative for the capture of person/object presence and location data. In contrast, a sensor, such as a LIDAR sensor, can provide targeted and detailed presence and location data.

Some examples in this regard enable tight correlations to be drawn, allowing tool manufacturers, for example, to block empty spaces around their installed tools or enhance tool density in a fabrication room (fab) while optimizing wireless connectivity between connected devices. Some examples incorporate feedback from a sensor to adjust or manage the sending of wireless signals to a calibration wafer, for example. So, in addition to learning that a detected person or object is interfering with a given wireless signal, some examples use feedback data in real time to improve the connectivity between a router and an APS sensor or calibration wafer. Information captured by the sensor is correlated with wireless signal strength in a virtuous or positive feedback loop in some examples (e.g., using a wireless signal strength graph such as graph 650 in FIG. 6C).

Some examples enable fault finding or the cause of a tool downtime. For example, a calibration or wafer placement error might, under the correlation and matching techniques described herein, actually and more accurately be ascribed to the presence of an obstructing object/person in the access zone causing a signal disruption, as opposed to a suspected (but incorrect) failure of the placement robot itself.

In some embodiments, there is provided a system for sensor-assisted signal calibration of a semiconductor processing tool. The system includes a sensor array comprising a plurality of range-finding sensors (e.g., TOF sensors 936 in FIG. 9). The plurality of range-finding sensors are disposed within an access zone (e.g., access zone 928) of the semiconductor processing tool. The system further includes a controller (e.g., wireless connectivity controller 320) communicatively coupled to the sensor array. The controller is configured to decode a corresponding plurality of sensor measurements received from the plurality of range-finding sensors. The controller is further configured to detect a presence of a disrupting object within the access zone of the semiconductor processing tool based on the corresponding plurality of sensor measurements. The controller is further configured to detect a deviation of at least one signal characteristic of a wireless signal from a pre-configured value, where the wireless signal propagates through the access zone. The deviation is detected while the disrupting object is present within the access zone. The controller is further configured to perform a mitigation action associated with the wireless signal based on detecting the deviation.

In some aspects, to perform the mitigation action, the controller is further configured to adjust at least one signal characteristic of the wireless signal to reach the pre-configured value.

In some aspects, to perform the mitigation action, the controller is further configured to generate a notification of the presence of the disrupting object detected within the access zone and cause communication of the notification within the access zone.

In some embodiments, the plurality of range-finding sensors comprises at least a first two-dimensional (2D) light detection and ranging (LIDAR) sensor, a second 2D LIDAR sensor, and a third 2D LIDAR sensor disposed within the access zone.

In some aspects, the controller is further configured to decode the corresponding plurality of sensor measurements to determine measurements from the first 2D LIDAR sensor, the second 2D LIDAR sensor, and the third 2D LIDAR sensor.

In some aspects, the measurements include a first distance from the first 2D LIDAR sensor to the disrupting object, a second distance from the second 2D LIDAR sensor to the disrupting object, and a third distance from the third 2D LIDAR sensor to the disrupting object.

In some embodiments, the controller is further configured to determine spatial coordinates of the disrupting object within the access zone based on the first distance, the second distance, and the third distance. The controller is further configured to cause re-routing of the wireless signal based on the spatial coordinates of the disrupting object.

In some embodiments, the plurality of range-finding sensors include a three-dimensional (3D) light detection and ranging (LIDAR) sensor, and the controller is further configured to decode the corresponding plurality of sensor measurements to determine measurements from the 3D LIDAR sensor.

In some aspects, the controller is further configured to determine the spatial coordinates of the disrupting object within the access zone based on the measurements from the 3D LIDAR sensor and cause re-routing of the wireless signal based on the spatial coordinates of the disrupting object.

In some aspects, the controller is further configured to detect the deviation of at least one signal characteristic of the wireless signal from the pre-configured value is greater than a threshold value and modify at least one process performed by the semiconductor processing tool based on detecting the deviation is greater than the threshold value.

In some aspects, the access zone is defined, at least in part, by the walls of a vacuum transfer module (VTM) and an equipment front-end module (EFEM) of the semiconductor processing tool.

In some embodiments, the controller is further configured to decode the corresponding plurality of sensor measurements to determine a wireless connectivity parameter associated with the semiconductor processing tool. The wireless connectivity parameter includes one or more of a wireless frequency, a wireless channel, a wireless signal strength, a wireless coverage area, and a wireless signal dead zone.

In some aspects, the controller is further configured to generate a correlation between the wireless connectivity parameter and the detected presence of the disrupting object or movement of the disrupting object within the access zone. The controller is further configured to generate an instruction associated with at least one process performed by the semiconductor processing tool, where the instruction is based on the correlation.

In some aspects, the controller is further configured to perform fine-tuning of a wafer calibration routine or a placement routine of the semiconductor processing tool based on the instruction.

In some embodiments, the controller is further configured to generate a correlation between the wireless connectivity parameter and an aspect of a component of the semiconductor processing tool and generate an instruction associated with at least one process performed by the semiconductor processing tool, the instruction based on the correlation.

In some aspects, the component of the semiconductor processing tool includes one or more of a group of components, including a vacuum transfer module (VTM), an equipment front-end module (EFEM), a load lock, a process module, a transfer robot, a loading station, an EFEM back wall, a VTM top wall, a wafer-handling robot, a vacuum transfer robot, an external storage buffer, an internal storage buffer, an autocalibration controller, a wireless connectivity controller, and an end effector of the wafer-handling robot.

In some embodiments, the aspect of the component of the semiconductor processing tool includes one or more of a group of aspects, including the location of the component, a dimension or size of the component, the number of components, a configuration of the component, and a tool density affected by the aspect of the component.

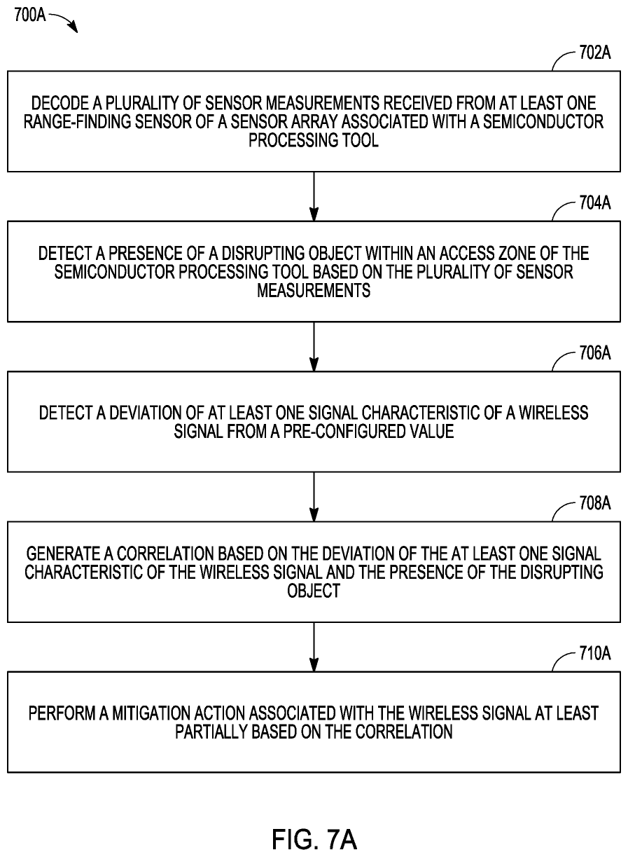

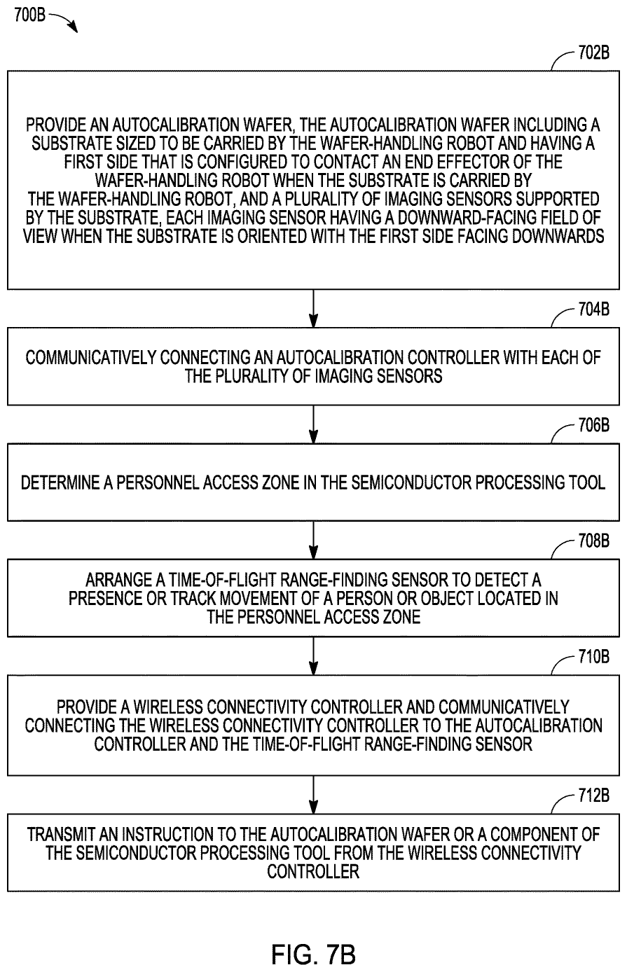

FIG. 7A illustrates method 700A for sensor-assisted signal calibration of a semiconductor processing tool in accordance with an example embodiment. At operation 702A, a plurality of sensor measurements received from at least one range-finding sensor of a sensor array associated with a semiconductor processing tool are decoded. At operation 704A, a presence of a disrupting object within an access zone of the semiconductor processing tool is detected based on the plurality of sensor measurements. At operation 706A, a deviation of at least one signal characteristic of a wireless signal from a pre-configured value is detected. At operation 708A, a correlation is generated based on the deviation of the at least one signal characteristic of the wireless signal and the presence of the disrupting object. At operation 710A, a mitigation action associated with the wireless signal is performed at least partially based on the correlation.

In some aspects, the performing of the mitigation action further includes adjusting at least one signal characteristic of the wireless signal to reach the pre-configured value.

In some aspects, the performing of the mitigation action further includes generating a notification of the presence of the disrupting object detected within the access zone and causing communication of the notification within the access zone.

In some embodiments, the at least one range-finding sensor includes at least a first two-dimensional (2D) light detection and ranging (LIDAR) sensor, a second 2D LIDAR sensor, and a third 2D LIDAR sensor disposed within the access zone.

In some aspects, method 700A further includes decoding the plurality of sensor measurements to determine measurements from the first 2D LIDAR sensor, the second 2D LIDAR sensor, and the third 2D LIDAR sensor.

In some embodiments, the measurements include a first distance from the first 2D LIDAR sensor to the disrupting object, a second distance from the second 2D LIDAR sensor to the disrupting object, and a third distance from the third 2D LIDAR sensor to the disrupting object.

In some embodiments, method 700A further includes determining spatial coordinates of the disrupting object within the access zone based on the first distance, the second distance, and the third distance. In some embodiments, method 700A further includes causing re-routing of the wireless signal based on the spatial coordinates of the disrupting object.

In some aspects, the plurality of range-finding sensors includes a three-dimensional (3D) light detection and ranging (LIDAR) sensor. In some aspects, method 700A further includes decoding the plurality of sensor measurements to determine measurements from the 3D LIDAR sensor.

In some embodiments, method 700A further includes determining spatial coordinates of the disrupting object within the access zone based on the measurements from the 3D LIDAR sensor and causing re-routing of the wireless signal based on the spatial coordinates of the disrupting object.

In some embodiments, method 700A further includes detecting the deviation of the at least one signal characteristic of the wireless signal from the pre-configured value is greater than a threshold value, and modifying at least one process performed by the semiconductor processing tool based on detecting the deviation is greater than the threshold value.

FIG. 7B illustrates method 700B of assisting calibration of a wafer-handling robot for a semiconductor processing tool in accordance with an example embodiment. At operation 702A, method 700B provides an autocalibration wafer, the autocalibration wafer including a substrate sized to be carried by the wafer-handling robot and having a first side that is configured to contact an end effector of the wafer-handling robot when the substrate is carried by the wafer-handling robot, and a plurality of imaging sensors supported by the substrate, each imaging sensor having a downward-facing field of view when the substrate is oriented with the first side facing downwards.

At operation 704B, method 700B communicatively connects an autocalibration controller with each of the plurality of imaging sensors. At operation 706B, method 700B determines an access zone in the semiconductor processing tool. At operation 708B, method 700B arranges a time-of-flight range-finding sensor to detect the presence or track movement of a person or object located in the access zone. At operation 710B, method 700B provides a wireless connectivity controller and communicatively connects the wireless connectivity controller to the autocalibration controller and the time-of-flight range-finding sensor. At operation 712B, method 700B transmits an instruction to the autocalibration wafer or a component of the semiconductor processing tool from the wireless connectivity controller.

In some examples, the time-of-flight range-finding sensor is a LIDAR sensor. In some examples, the access zone is defined at least in part by the walls of a vacuum transfer module (VTM) and an equipment front-end module (EFEM) of the semiconductor processing tool. In some examples, method 700B further includes transmitting presence detection or movement data captured by the time-of-flight range-finding sensor to the wireless connectivity controller and, at the wireless connectivity controller, processing a wireless connectivity parameter of the semiconductor processing tool.

In some examples, the wireless connectivity parameter includes one or more of a group of wireless connectivity parameters comprising a wireless frequency, a wireless channel, a wireless signal strength, a wireless coverage area, and a wireless signal dead zone. In some examples, method 700B further includes configuring the wireless connectivity controller to generate a correlation between the wireless connectivity parameter and a detected presence or tracked movement of a person or object in the access zone.

In some examples, method 700B further includes configuring the wireless connectivity controller to transmit the instruction to the autocalibration controller based on the correlation. In some examples, method 700B further includes fine-tuning a wafer calibration or placement routine based on the instruction.

In some examples, method 700B further includes configuring the wireless connectivity controller to generate a correlation between the wireless connectivity parameter and an aspect of a component of the semiconductor processing tool.

In some examples, the component of the semiconductor processing tool includes one or more of a group of components comprising a vacuum transfer module (VTM), an equipment front-end module (EFEM), a load lock, a process module, a transfer robot, a loading station, an EFEM back wall, a VTM top wall, a wafer handling robot, a vacuum transfer robot, an external storage buffer, an internal storage buffer, the autocalibration controller, the wireless connectivity controller, and the end effector of the wafer-handling robot.

In some examples, the aspect of the component of the semiconductor processing tool includes one or more of a group of aspects comprising a location of the component, a dimension or size of the component, a number of components, a configuration of the component, and a tool density affected by the aspect of the component.

FIG. 8 is a block diagram illustrating an example of a machine or controller 800 by which one or more example embodiments described herein may be implemented or controlled. In alternative embodiments, the controller 800 may operate as a standalone device or may be connected (e.g., networked) to other machines. In a networked deployment, the controller 800 may operate in the capacity of a server machine, a client machine, or both in server-client network environments. In an example, the controller 800 may act as a peer machine in a peer-to-peer (P2P) (or other distributed) network environment. Further, while only a single controller 800 is illustrated, the term “machine” (controller) shall also be taken to include any collection of machines (controllers) that individually or jointly execute a set (or multiple sets) of instructions to perform any one or more of the methodologies discussed herein, such as via cloud computing, software as a service (Saas), or other computer cluster configurations. In some examples, and referring to FIG. 8, a non-transitory machine-readable medium includes instructions 824, which, when read by the controller 800, causes the controller to control operations in methods comprising at least the non-limiting example operations described herein.

In some examples, a non-transitory computer-readable storage medium including instructions that, when executed by a computer, cause the computer to communicatively connect an autocalibration controller with each of a plurality of imaging sensors of an autocalibration wafer, communicate with a time-of-flight range-finding sensor to detect a presence or track movement of a person or object located in an access zone in a semiconductor processing tool; process communications between a wireless connectivity controller and the autocalibration controller and the time-of-flight range-finding sensor, and transmit an instruction to the autocalibration wafer or a component of the semiconductor processing tool from the wireless connectivity controller.

Examples, as described herein, may include, or may operate by logic, a number of components or mechanisms. Circuitry is a collection of circuits implemented in tangible entities that include hardware (e.g., simple circuits, gates, logic, etc.). Circuitry membership may be flexible over time and underlying hardware variability. Circuitries include members that may, alone or in combination, perform specified operations when operating. In an example, the hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, by moveable placement of invariant massed particles, etc.) to encode instructions of the specific operation. In connecting the physical components, the underlying electrical properties of a hardware constituent are changed (for example, from an insulator to a conductor or vice versa). The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry or by a third circuit in a second circuitry at a different time.

The machine (e.g., computer system) controller 800 may include a hardware processor 802 (e.g., a central processing unit (CPU), a hardware processor core, or any combination thereof), a graphics processing unit (GPU) 832 (graphics processing unit), a main memory 804, and a static memory 806, some or all of which may communicate with each other via an interlink 818 (e.g., a bus). Controller 800 may further include a display device 808, an alphanumeric input device 810 (e.g., a keyboard), and a user interface (UI) navigation device 812 (e.g., a mouse or other user interface). In an example, the display device 808, alphanumeric input device 810, and UI navigation device 812 may be a touch screen display. The controller 800 may additionally include a mass storage device 814 (e.g., drive unit), a signal generation device 816 (e.g., a speaker), a network interface device 820, and one or more sensors 830, such as a Global Positioning System (GPS) sensor, compass, accelerometer, or another sensor. The controller 800 may include an output controller 828, such as a serial (e.g., universal serial bus (USB)), parallel, or other wired or wireless (e.g., infrared (IR), near field communication (NFC), etc.) connection to communicate with or control one or more peripheral devices (e.g., a printer, card reader, etc.).

The mass storage device 814 may include a machine-readable medium 822 on which is stored one or more sets of data structures or instructions 824 (e.g., software) embodying or utilized by any one or more of the techniques or functions described herein. The instructions 824 may, as shown, also reside, entirely or at least partially, within the main memory 804, within the static memory 806, within the hardware processor 802, or the GPU 832 during execution thereof by the controller 800. In an example, one or any combination of the hardware processor 802, the GPU 832, the main memory 804, the static memory 806, or the mass storage device 814 may constitute the machine-readable medium 822.

While the machine-readable medium 822 is illustrated as a single medium, the term “machine-readable medium” may include a single medium, or multiple media (e.g., a centralized or distributed database, and/or associated caches and servers) configured to store the one or more instructions 824.

The term “machine-readable medium” may include any medium that can store, encode, or carry instructions 824 for execution by the controller 800 and that causes the controller 800 to perform any one or more of the techniques of the present disclosure, or that can store, encode, or carry data structures used by or associated with such instructions 824. Non-limiting machine-readable medium examples may include solid-state memories and optical and magnetic media. In an example, a massed machine-readable medium comprises a machine-readable medium 822 with a plurality of particles having invariant (e.g., rest) mass. Accordingly, massed machine-readable media are not transitory propagating signals. Specific examples of massed machine-readable media may include non-volatile memory, such as semiconductor memory devices (e.g., electrically programmable read-only memory (EPROM), electrically erasable programmable read-only memory (EEPROM)) and flash memory devices; magnetic disks, such as internal hard disks and removable disks; magneto-optical disks; and CD-ROM and DVD-ROM disks. Instructions 824 may further be transmitted or received over a communications network 826 using a transmission medium via the network interface device 820.

FIG. 9 shows a plan view of an example system for characterizing a wireless environment 934 around a semiconductor processing tool 902 according to an embodiment of the present disclosure. The semiconductor processing tool 902 includes an EFEM 904, load locks 906, processing modules 908, VTM 910, a transfer robot 912 of the EFEM 904 (which is arranged between the loading stations 914 on a front wall and a back wall 916 of the EFEM 904), vacuum transfer robots 918, one or more external storage buffers 920, and one or more internal storage buffers 922. Although shown as having one or two arms, each of the vacuum transfer robots 918 may have configurations including one, two, or more arms. In some examples, the vacuum transfer robot 918 may include two end effectors 924 on each of the arms, as shown in FIG. 9.

In some examples, the wireless environment 934 includes a wireless router 932 mounted on the EFEM 904, where wireless signals communicated via the wireless router 932 can pass through access zone 928. The wireless environment 934 may also include other mobile or stationary sensors wirelessly connected to each other. For example, a mobile sensor or a set of mobile sensors within the wireless environment 934 may include one or more APS wafers 930, as discussed herein above.

In some embodiments, the wireless environment 934 can include stationary sensors such as a wireless environment sensor 926, a material sensor 938, and one or more TOF sensors such as TOF sensors 936A, 936B, 936C, 936D, 936E, and 936F (collectively, TOF sensors 936). Even though FIG. 9 illustrates the wireless environment 934 to include a single wireless environment sensor, a single material sensor, and six TOF sensors, the disclosure is not limited in this regard and other sets and/or arrangements of stationary and mobile sensors are possible based on desired sensor coverage, space restrictions, or implementation considerations.

In some aspects, the wireless environment sensor 926 comprises suitable circuitry, logic, interfaces, and/or code and is configured to measure radio frequency (RF) noise within the wireless environment 934. In some aspects, the wireless environment sensor 926 is located in the vicinity of (e.g., within a pre-configured distance from) the access zone 928. The wireless connectivity controller 320 (or another controller used by the semiconductor processing tool 902) can use sensor data from the wireless environment sensor 926 to detect the presence of (or changes in) RF interference within the access zone 928 as well as the presence of other wireless devices or sensors. In some aspects, a mitigation action can be performed if the detected RF interference is above a threshold level. Example mitigation actions include generating a notification of the elevated RF interference level and adjusting one or more wireless signal characteristics of signals communicated through access zone 928 (e.g., increasing signal power, adjusting signal modulation, adjusting antenna directionality, etc.).

In some aspects, the material sensor 938 comprises suitable circuitry, logic, interfaces, and/or code and is configured to detect an object in its FoV and perform material analysis to determine one or more materials that the detected object is composed of. In some aspects, the material sensor 938 is configured to perform spectroscopic analysis to detect the material composition of the object (or objects) in its FoV.

In some embodiments, the TOF sensors 936 are similar to the one or more sensors 126, the one or more sensors 316, or the one or more sensors 406 discussed herein. In some aspects, at least three of the TOF sensors 936 can be 2D LIDAR sensors and can be arranged at a pre-configured distance from access zone 928. For example, TOF sensors 936A, 936B, and 936E can be 2D LIDAR sensors which can be used to detect a disrupting object within the access zone 928 and generate sensor measurements which can be used to determine corresponding distances between each of the sensors and the disrupting object. The corresponding distances can be used (e.g., by the wireless connectivity controller 320 or another controller used by the semiconductor processing tool 902) to determine spatial coordinates of the disrupting object (e.g., if the disrupting object is stationary) as well as movement path and trajectory coordinates (e.g., if the disrupting object is moving within the access zone 928). Such information is then used to perform a mitigation action, which can include generating a notification, adjusting one or more wireless signal characteristics of wireless signals communicated through the access zone 928, re-calibrating or re-configuring at least one process performed by the semiconductor processing tool 902 (e.g., a process based on the wireless signals that have been affected by the presence/movement of the disrupting object within the access zone 928), fault analysis, optimization of wireless connectivity, fine-tuning of substrate processing parameters, etc.

In some aspects, at least one of the TOF sensors 936 (e.g., TOF sensor 936B) can be a 3D LIDAR sensor and can be arranged at a pre-configured distance from access zone 928. For example, TOF sensor 936B can be used to detect a disrupting object within access zone 928 and generate sensor measurements, including spatial coordinates of the detected disrupting object.

In some embodiments, one or more of the TOF sensors 936A-936F are arranged in the proximity of the access zone (e.g., TOF sensors 936A, 936B, and 936E) as well as in the proximity of surrounding areas of the semiconductor processing tool 902. For example, TOF sensors 936C, 936D, 936B, 936E, and 936F can also be used to detect the presence of disruptive objects in the surrounding areas around the semiconductor processing tool 902 that are outside of the access zone 928 but within the wireless environment 934. Corresponding mitigation action (or actions) can be performed if a disrupting object is detected within such surrounding areas.

In some embodiments, the mobile and stationary sensors within the wireless environment 934 discussed above can be networked together (e.g., as part of a wired or wireless network) so that sensor data from multiple different sensors can be continuously (or periodically) monitored to assess for the presence of a disruptive object or change in one or more wireless signal characteristics of signals traversing the wireless environment 934 that are used by the semiconductor processing tool 902. Corresponding mitigation action (or actions) can be performed based on the sensor input from one or more of the networked sensors within the wireless environment 934. In some aspects, the networked sensors can inform aspects such as tool configuration and personnel and/or object access permission to optimize wireless connectivity in the wireless environment 934 that might, for example, impact the propagation of a desired wireless signal. This information may be used once during tool setup or may be required before every wireless sensor data collection period.

Systems and methods, according to the principles of the present disclosure, provide various configurations of processing tools and sensors to maximize the wireless connectivity of processing tool components. It will be appreciated that any interruption of the wireless connection between the wirelessly connected components and the autocalibration wafer can have significant adverse effects. For example, personnel presence and disruptive foreign objects placed in a path between the semiconductor processing tool and an autocalibration wafer can interfere with wireless connectivity and cause calibration and placement faults. The provision of a wireless environment sensor 926 and other sensors, as described above, allows insights into this interference and enables characterization of a wireless environment 934 and informed analysis of faults, leading to enhanced calibration and placement routines and enhanced fabrication room configurations and tool densities.

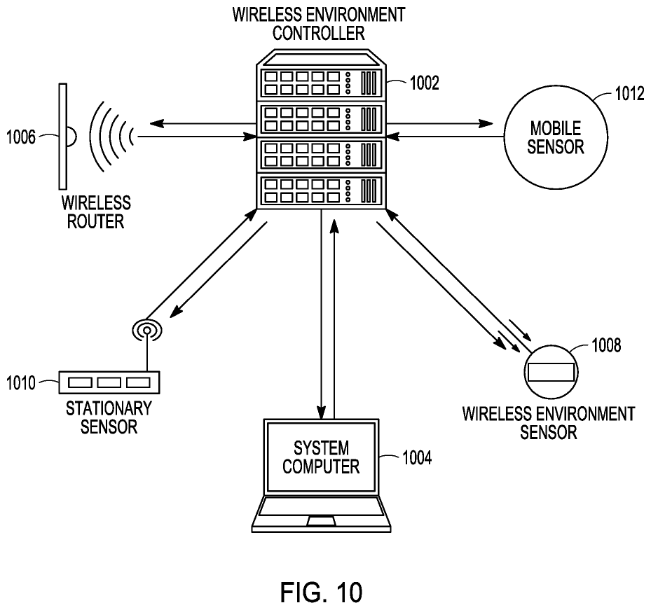

Concerning FIG. 10, in some implementations, a wireless environment controller 1002 receives input from one or more environment devices and/or sensors, as shown. The devices and/or sensors may include a wireless router 1006, a wireless environment sensor 1008, a stationary sensor 1010, and a mobile sensor 1012. These sensors may or may not be wireless themselves, but some examples are sensors that characterize the wireless environment surrounding or part of a semiconductor processing tool, such as the wireless environment 934 of the semiconductor processing tool 902 of FIG. 9. The wireless environment controller 1002 communicates with the wireless router 1006, and the mobile sensor 1012, such as an APS, and the system computer 1004, such as a system computer. Some examples of interactions include the wireless environment controller 1002 instructing the system computer 1004 to delay running APS until wireless environment parameters meet certain levels. Another example of interaction is the wireless environment controller 1002 instructing the wireless router 1006 to increase the transmission power, change the wireless channel, or change signal modulation. The wireless environment controller 1002 can inform the mobile sensor 1012 (such as the APS) or the stationary sensor 1010 to have its wireless controller send packets of information in smaller sizes or delay transmission of information until it has moved to a location within the wireless environment 934 with less interference. In some examples, the wireless router 1006 can also act as a wireless environment sensor 1008.

In some embodiments, the wireless environment controller 1002 is implemented as part of the semiconductor processing tool. In other aspects, the wireless environment controller 1002 is an off-the-tool controller that can be configured as a stand-alone device or as part of another computing device (e.g., a field engineer's tablet or smartphone).

Although examples have been described concerning specific example embodiments or methods, it will be evident that various modifications and changes may be made to these embodiments without departing from the broader scope of the embodiments. Accordingly, the specification and drawings are to be regarded in an illustrative rather than a restrictive sense. The accompanying drawings that form a part hereof show, by way of illustration and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This detailed description, therefore, is not to be taken in a limiting sense, and the scope of various embodiments is defined only by the appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is disclosed. Thus, although specific embodiments have been illustrated and described herein, it should be appreciated that any arrangement calculated to achieve the same purpose may be substituted for the specific embodiments shown. This disclosure is intended to cover any adaptations or variations of various embodiments. Combinations of the above embodiments and other embodiments not explicitly described herein will be apparent to those of skill in the art upon reviewing the above description.

1. A system for sensor-assisted signal calibration of a semiconductor processing tool, the system comprising:
a sensor array comprising at least one range-finding sensor, the at least one range-finding sensor disposed within an access zone of the semiconductor processing tool; and
a controller communicatively coupled to the sensor array, the controller configured to:
decode a plurality of sensor measurements received from the at least one range-finding sensor;
detect a presence of a disrupting object within the access zone of the semiconductor processing tool based on the plurality of sensor measurements;
detect a deviation of at least one signal characteristic of a wireless signal from a pre-configured value,
generate a correlation based on the deviation of the at least one signal characteristic of the wireless signal and the presence of the disrupting object; and
perform a mitigation action associated with the wireless signal at least partially based on the correlation.

2. The system of claim 1, wherein to perform the mitigation action the controller is further to:
adjust the at least one signal characteristic of the wireless signal to reach the pre-configured value.

3. The system of claim 1, wherein to perform the mitigation action the controller is further configured to:
generate a notification of the presence of the disrupting object detected within the access zone; and
cause communication of the notification within the access zone.

4. The system of claim 1, wherein the at least one range-finding sensor comprises at least a first two-dimensional (2D) light detection and ranging (LIDAR) sensor, a second 2D LIDAR sensor, and a third 2D LIDAR sensor disposed within the access zone.

5. The system of claim 4, wherein the controller is further to:
decode the plurality of sensor measurements to determine measurements from the first 2D LIDAR sensor, the second 2D LIDAR sensor, and the third 2D LIDAR sensor.

6. The system of claim 5, wherein the measurements comprise:
a first distance from the first 2D LIDAR sensor to the disrupting object;
a second distance from the second 2D LIDAR sensor to the disrupting object; and
a third distance from the third 2D LIDAR sensor to the disrupting object.

7. The system of claim 6, wherein the controller is further to:
determine spatial coordinates of the disrupting object within the access zone based on the first distance, the second distance, and the third distance; and
cause re-routing of the wireless signal based on the spatial coordinates of the disrupting object.

8. The system of claim 1, wherein the at least one range-finding sensor comprises a three-dimensional (3D) light detection and ranging (LIDAR) sensor, and wherein the controller is further to:
decode the plurality of sensor measurements to determine measurements from the 3D LIDAR sensor.

9. The system of claim 8, wherein the controller is further to:
determine spatial coordinates of the disrupting object within the access zone based on the measurements from the 3D LIDAR sensor; and
cause re-routing of the wireless signal based on the spatial coordinates of the disrupting object.

10. The system of claim 1, wherein the controller is further to:
detect the deviation of the at least one signal characteristic of the wireless signal from the pre-configured value is greater than a threshold value; and
modify at least one process performed by the semiconductor processing tool based on detecting the deviation is greater than the threshold value.

11. The system of claim 1, wherein the access zone is defined at least in part by walls of a vacuum transfer module (VTM) and an equipment front-end module (EFEM) of the semiconductor processing tool.

12. The system of claim 1, wherein the controller is further to:
decode the plurality of sensor measurements to determine a wireless connectivity parameter associated with the semiconductor processing tool, the wireless connectivity parameter comprising one or more of a wireless frequency, a wireless channel, a wireless signal strength, a wireless coverage area, and a wireless signal dead zone.

13. The system of claim 12, wherein the controller is further to:
generate a correlation between the wireless connectivity parameter and the detected presence of the disrupting object or movement of the disrupting object within the access zone; and
generate an instruction associated with at least one process performed by the semiconductor processing tool, the instruction being based on the correlation.

14. The system of claim 13, wherein the controller is further to:
perform fine-tuning of a wafer calibration routine or a placement routine of the semiconductor processing tool based on the instruction.

15. The system of claim 12, wherein the controller is further to:
generate a correlation between the wireless connectivity parameter and an aspect of a component of the semiconductor processing tool; and
generate an instruction associated with at least one process performed by the semiconductor processing tool, the instruction being based on the correlation.

16. The system of claim 15, wherein the component of the semiconductor processing tool includes one or more of a group of components comprising: a vacuum transfer module (VTM), an equipment front-end module (EFEM), a load lock, a process module, a transfer robot, a loading station, an EFEM back wall, a VTM top wall, a wafer-handling robot, a vacuum transfer robot, an external storage buffer, an internal storage buffer, an autocalibration controller, a wireless connectivity controller, and an end effector of the wafer-handling robot.

17. The system of claim 16, wherein the aspect of the component of the semiconductor processing tool includes one or more of a group of aspects comprising: a location of the component, a dimension or size of the component, a number of components, a configuration of the component, and a tool density affected by the aspect of the component.

18. A method for sensor-assisted signal calibration of a semiconductor processing tool, the method comprising:
decoding a plurality of sensor measurements received from at least one range-finding sensor of a sensor array associated with the semiconductor processing tool;
detecting a presence of a disrupting object within an access zone of the semiconductor processing tool based on the plurality of sensor measurements;
detecting a deviation of at least one signal characteristic of a wireless signal from a pre-configured value;
generating a correlation based on the deviation of the at least one signal characteristic of the wireless signal and the presence of the disrupting object; and
performing a mitigation action associated with the wireless signal at least partially based on the correlation.

19. The method of claim 18, wherein the performing of the mitigation action further comprises:
adjusting the at least one signal characteristic of the wireless signal to reach the pre-configured value.

20. The method of claim 18, wherein the performing of the mitigation action further comprises:
generating a notification of the presence of the disrupting object detected within the access zone; and
causing communication of the notification within the access zone.

21. The method of claim 18, wherein the at least one range-finding sensor comprises at least a first two-dimensional (2D) light detection and ranging (LIDAR) sensor, a second 2D LIDAR sensor, and a third 2D LIDAR sensor disposed within the access zone.

22. The method of claim 21, further comprising:
decoding the plurality of sensor measurements to determine measurements from the first 2D LIDAR sensor, the second 2D LIDAR sensor, and the third 2D LIDAR sensor.

23. The method of claim 22, wherein the measurements comprise:
a first distance from the first 2D LIDAR sensor to the disrupting object;
a second distance from the second 2D LIDAR sensor to the disrupting object; and
a third distance from the third 2D LIDAR sensor to the disrupting object.

24. The method of claim 23, further comprising:
determining spatial coordinates of the disrupting object within the access zone based on the first distance, the second distance, and the third distance; and
causing re-routing of the wireless signal based on the spatial coordinates of the disrupting object.

25. The method of claim 18, wherein the at least one range-finding sensor comprises a three-dimensional (3D) light detection and ranging (LIDAR) sensor, and the method further comprises:
decoding the plurality of sensor measurements to determine measurements from the 3D LIDAR sensor.

26. The method of claim 25, further comprising:
determining spatial coordinates of the disrupting object within the access zone based on the measurements from the 3D LIDAR sensor; and
causing re-routing of the wireless signal based on the spatial coordinates of the disrupting object.

27. The method of claim 18, further comprising:
detecting the deviation of the at least one signal characteristic of the wireless signal from the pre-configured value is greater than a threshold value; and
modifying at least one process performed by the semiconductor processing tool based on detecting the deviation is greater than the threshold value.

28. A method for sensor-assisted signal calibration of a semiconductor processing tool, the method comprising:
providing an autocalibration wafer, the autocalibration wafer including a substrate sized to be carried by a wafer-handling robot and having a first side that is configured to contact an end effector of the wafer-handling robot when the substrate is carried by the wafer-handling robot, and a plurality of imaging sensors supported by the substrate, each imaging sensor having a downward-facing field of view when the substrate is oriented with the first side facing downwards;
communicatively connecting an autocalibration controller with each of the plurality of imaging sensors;
determining an access zone in the semiconductor processing tool;
arranging a time-of-flight range-finding sensor to detect a presence or track movement of a person or object located in the access zone;
providing a wireless connectivity controller and communicatively connecting the wireless connectivity controller to the autocalibration controller and the time-of-flight range-finding sensor; and
transmitting an instruction to the autocalibration wafer or a component of the semiconductor processing tool from the wireless connectivity controller.
